(19) United States
(12) Patent Application Publication
(10) Pub. No.: US 2023/0411228 A1
(43) Pub. Date: Dec. 21, 2023

(54) SEMICONDUCTOR DEVICE AND METHOD OF MANUFACTURING THE SAME

(71) Applicant: Kioxia Corporation, Tokyo (JP)

(72) Inventors: Atsushi Oga, Yokkaichi Mie (JP); Masayoshi Tagami, Kuwana Mie (JP)

(73) Assignee: Kioxia Corporation, Tokyo (JP)

(21) Appl. No.: 18/180,926

(22) Filed: Mar. 9, 2023

(30) Foreign Application Priority Data
Jun. 21, 2022 (JP) 2022-099944

(51) Int. Cl. H01L 21/66; H01L 23/00; H10B 80/00

(52) U.S. Cl. CPC H01L 22/32; H01L 24/08; H01L 24/80; H10B 80/00; H01L 2924/14511; H01L 2224/80006; H01L 2224/80895; H01L 2224/80896; H01L 2924/1431; H01L 2224/08145

(57) ABSTRACT

In one embodiment, a semiconductor device includes a first interconnect including a first pad. The semiconductor device further includes a second pad provided on the first interconnect. In the semiconductor device, the second pad is in contact with another pad, and the first pad is not in contact with another pad.

### CROSS REFERENCE TO RELATED APPLICATION

This application is based upon and claims the benefit of priority from the prior Japanese Patent Application No. 2022-099944, filed on Jun. 21, 2022, the entire contents of which are incorporated herein by reference.

### FIELD

Embodiments described herein relate to a semiconductor device and a method of manufacturing the same.

### BACKGROUND

When semiconductor chips are manufactured by bonding a plurality of wafers, the yield of the semiconductor chips may decrease due to defects in chip areas in the respective wafers.

### BRIEF DESCRIPTION OF THE DRAWINGS

FIG. 1 is a cross-sectional view illustrating a structure of a semiconductor device of a first embodiment;

FIGS. 2A and 2B are cross-sectional views illustrating structures of memory cell arrays 22 and 32 of the first embodiment;

FIGS. 3 to 7 are cross-sectional views illustrating a method of manufacturing the semiconductor device of the first embodiment;

FIGS. 8A to 8C are views illustrating a structure of a circuit wafer W1 of the first embodiment;

FIGS. 9A to 9C are views illustrating a structure of an array wafer W2 of the first embodiment;

FIGS. 10A to 10C are views illustrating a structure of an array wafer W3 of the first embodiment;

FIGS. 11 and 12 are cross-sectional views illustrating details of the method of manufacturing the semiconductor device of the first embodiment;

FIGS. 13A to 16B are cross-sectional views illustrating details of the method of manufacturing the semiconductor device of the first embodiment;

FIG. 17 is a flowchart for illustrating a test method of the first embodiment;

FIGS. 18A to 18C are schematic views for illustrating the test method of the first embodiment;

FIGS. 19A and 19B are schematic views for illustrating a test method of a comparative example of the first embodiment; and

FIGS. 20A and 20B are schematic views for illustrating the test method of the first embodiment.

### DETAILED DESCRIPTION

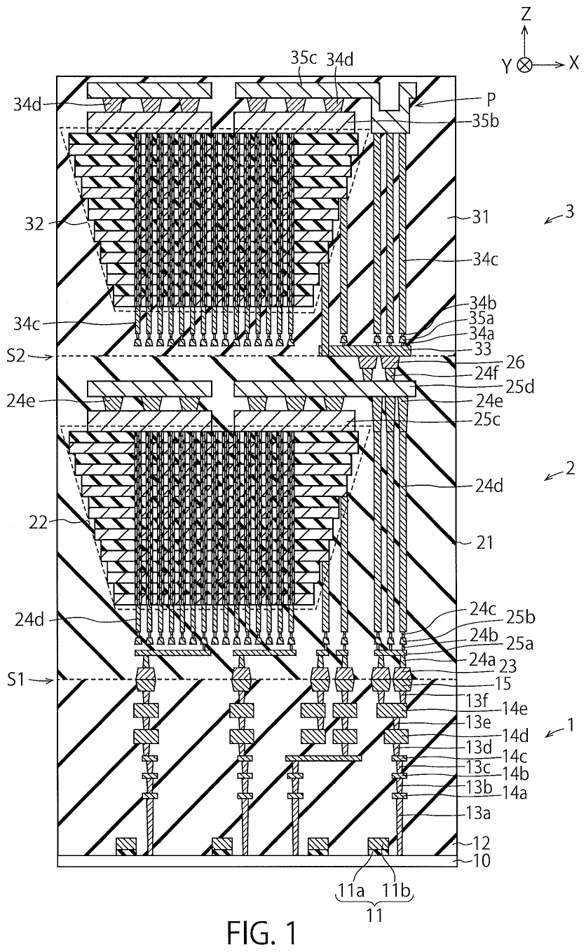

Embodiments will now be explained with reference to the accompanying drawings. In FIGS. 1 to 20B, identical components are denoted by identical reference signs, and repeated description will be omitted.

In one embodiment, a semiconductor device includes a first interconnect including a first pad, and a second pad provided on the first interconnect. The second pad is in contact with another pad, and the first pad is not in contact with another pad.

### First Embodiment

FIG. 1 is a cross-sectional view illustrating a structure of a semiconductor device of a first embodiment.

The semiconductor device of the present embodiment is a semiconductor chip including a three-dimensional memory, for example. The semiconductor device of the present embodiment is manufactured by bonding together a circuit wafer including a circuit chip 1, an array wafer including an array chip 2, and an array wafer including an array chip 3. FIG. 1 illustrates a bonding face S1 between the circuit chip 1 and the array chip 2, and a bonding face S2 between the array chip 2 and the array chip 3.

The circuit chip 1 includes a substrate 10, a plurality of transistors 11, an inter layer dielectric 12, a plurality of plugs 13a to 13f, a plurality of interconnects 14a to 14e, and a plurality of metal pads 15. The array chip 2 includes an inter layer dielectric 21, a memory cell array 22, a plurality of metal pads 23, a plurality of plugs 24a to 24f, a plurality of interconnects 25a to 25d, and a plurality of metal pads 26. The array chip 3 includes an inter layer dielectric 31, a memory cell array 32, a plurality of metal pads 33, a plurality of plugs 34a to 34d, and a plurality of interconnects 35a to 35c.

The substrate 10 is a semiconductor substrate, such as a Si (silicon) substrate, for example. FIG. 1 illustrates the X-direction and the Y-direction that are parallel with the surface of the substrate 10 and are perpendicular to each other, and also illustrates the Z-direction perpendicular to the surface of the substrate 10. The X-direction, the Y-direction, and the Z-direction cross each other. In this specification, the +Z-direction is handled as the upward direction, and the −Z-direction is handled as the downward direction. The −Z-direction may either coincide with or not coincide with the direction of gravity.

Each transistor 11 includes a gate insulator 11a and a gate electrode 11b formed in this order on the substrate 10, and also includes source and drain regions (not illustrated) formed in the substrate 10. The circuit chip 1 includes the plurality of transistors 11 on the substrate 10, and such transistors 11 form a CMOS circuit that controls the operation of the memory cell arrays 22 and 32, for example.

The inter layer dielectric 12 is formed on the substrate 10, and covers the transistors 11. The inter layer dielectric 12 is a stacked film of a SiO₂ film (i.e., silicon oxide film) and another insulator, for example. The inter layer dielectric 12 is an example of a first insulator.

Regarding the plugs 13a to 13f and the interconnects 14a to 14e, the plugs 13a, the interconnects 14a, the plugs 13b, the interconnects 14b, the plugs 13c, the interconnects 14c, the plugs 13d, the interconnects 14d, the plugs 13e, the interconnects 14e, and the plugs 13f are formed in this order on the substrate 10. The plugs 13a correspond to contact plugs, and the plugs 13b to 13f correspond to via plugs. Each plug 13a is arranged on the gate electrode 11b, the source region, or the drain region, for example. The plurality of interconnects 14a illustrated in FIG. 1 are provided in the same interconnect layer. This is also true of the plurality of interconnects 14b, the plurality of interconnects 14c, the plurality of interconnects 14d, and the plurality of interconnects 14e illustrated in FIG. 1. The plugs 13a to 13f and the interconnects 14a to 14e are provided in the inter layer dielectric 12.

The foregoing plurality of metal pads 15 are arranged on the respective plugs 13f in the inter layer dielectric 12. The metal pads 15 and the inter layer dielectric 12 form the upper face of the circuit chip 1, and are in contact with the lower face of the array chip 2. Each metal pad 15 includes a Cu (copper) layer, for example.

The inter layer dielectric 21 is formed on the inter layer dielectric 12. The inter layer dielectric 21 is a stacked film of a SiO₂ film and another insulator, for example. The inter layer dielectric 21 is an example of one of K second insulators (where K is an integer of one or more).

The memory cell array 22 is formed in the inter layer dielectric 21, and is arranged above the plugs 24d and below the interconnects 25c. The operation of the memory cell array 22 is controlled by the foregoing CMOS circuit via the metal pads 15 and 23. The memory cell array 22 includes a plurality of memory cells, and such memory cells can have data stored therein. The memory cell array 22 is an example of one of K memory cell arrays. The further details of the structure of the memory cell array 22 will be described later.

The foregoing plurality of metal pads 23 are arranged on the respective metal pads 15 in the inter layer dielectric 21. The metal pads 23 and the inter layer dielectric 21 form the lower face of the array chip 2, and are in contact with the upper face of the circuit chip 1. Each metal pad 23 includes a Cu layer, for example.

Regarding the plugs 24a to 24f and the interconnects 25a to 25d, the plugs 24a, the interconnects 25a, the plugs 24b, the interconnects 25b, the plugs 24c, the plugs 24d, the plugs 24e, the interconnects 25d, and the plugs 24f are formed in this order on the respective metal pads 23. Some of the plugs 24e are formed on the respective plugs 24d via the memory cell array 22 and the interconnects 25c. The plugs 24a to 24f correspond to via plugs. The plurality of interconnects 25a illustrated in FIG. 1 are provided in the same interconnect layer. This is also true of the plurality of interconnects 25b, the plurality of interconnects 25c, and the plurality of interconnects 25d illustrated in FIG. 1. The interconnects 25b below the memory cell array 22 function as bit lines, for example. The interconnects 25c above the memory cell array 22 function as source lines, for example. The plugs 24a to 24f and the interconnects 25a to 25e are provided in the inter layer dielectric 21.

The foregoing plurality of metal pads 26 are arranged on the respective plugs 24f in the inter layer dielectric 21. The metal pads 26 and the inter layer dielectric 21 form the upper face of the array chip 2, and are in contact with the lower face of the array chip 3. Each metal pad 26 includes a Cu layer, for example.

The inter layer dielectric 31 is formed on the inter layer dielectric 21. The inter layer dielectric 31 is a stacked film of a SiO₂ film and another insulator, for example. The inter layer dielectric 31 is also an example of one of the foregoing K second insulators.

The memory cell array 32 is formed in the inter layer dielectric 31, and is arranged above the plugs 34c and below the interconnects 35b. The operation of the memory cell array 32 is controlled by the foregoing CMOS circuit via the metal pads 15 and 23 and the metal pads 26 and 33. The memory cell array 32 includes a plurality of memory cells, and such memory cells can have data stored therein. The memory cell array 32 is also an example of one of the foregoing K memory cell arrays. The further details of the structure of the memory cell array 32 will be described below.

The foregoing plurality of metal pads 33 are arranged on the respective metal pads 26 in the inter layer dielectric 31. The metal pads 33 and the inter layer dielectric 31 form the lower face of the array chip 3, and are in contact with the upper face of the array chip 2. FIG. 1 illustrates one of such metal pads 33. Each metal pad 33 includes a Cu layer, for example.

Regarding the plugs 34a to 34d and the interconnects 35a to 35c, the plugs 34a, the interconnects 35a, the plugs 34b, the plugs 34c, and the interconnects 35c are formed in this order on the metal pad 33. The interconnects 35c are further formed on the plugs 34c via the memory cell array 32, the interconnects 35b and the plugs 34d. The plugs 34a to 34d correspond to via plugs. The plurality of interconnects 35a illustrated in FIG. 1 are provided in the same interconnect layer. This is also true of the plurality of interconnects 35b and the plurality of interconnects 35c illustrated in FIG. 1. The interconnects 35a below the memory cell array 32 function as bit lines, for example. The interconnects 35b above the memory cell array 32 function as source lines, for example. The interconnects 35c include a bonding pad P, for example. The plugs 34a to 34d and the interconnects 35a to 35c are provided in the inter layer dielectric 31.

Although the semiconductor device of the present embodiment includes the two array chips 2 and 3, it may include three or more array chips or may include only a single array chip instead. In such a case, the value of the foregoing K is a positive integer other than 2.

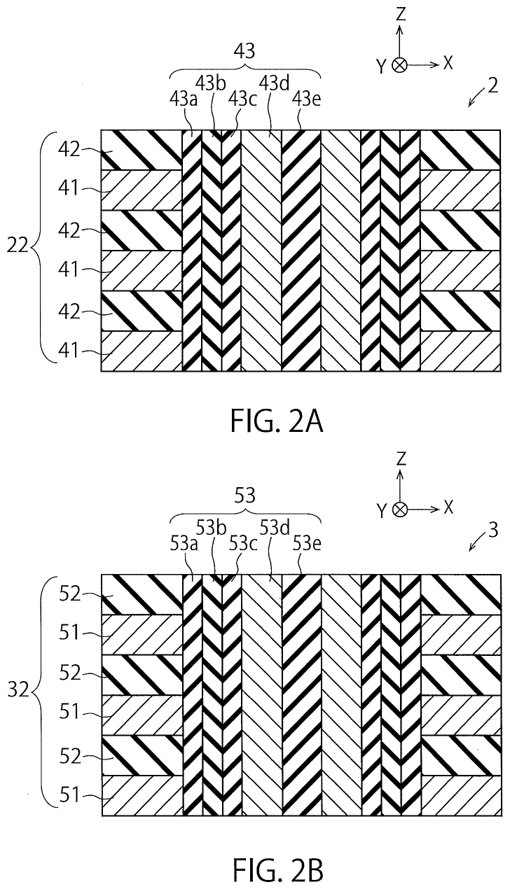

FIGS. 2A and 2B are cross-sectional views illustrating structures of the memory cell arrays 22 and 32 of the first embodiment.

The memory cell array 22 includes, as illustrated in FIG. 2A, a plurality of electrode layers 41, a plurality of insulators 42, and a plurality of columnar portions 43. FIG. 2A illustrates an example of one of the plurality of columnar portions 43.

The foregoing plurality of electrode layers 41 and the foregoing plurality of insulators 42 are alternately stacked along the Z-direction. Each electrode layer 41 includes a W (tungsten) layer, for example, and functions as a word line or a selection line. Each insulator 42 is a SiO₂ film, for example.

Each columnar portion 43 includes a block insulator 43a, a charge storage layer 43b, a tunnel insulator 43c, a channel semiconductor layer 43d, and a core insulator 43e that are formed in this order on the side faces of the electrode layers 41 and the insulators 42. The block insulator 43a is a SiO₂ film, for example. The charge storage layer 43b is an insulator, such as a SiN film (silicon nitride film), for example. The charge storage layer 43b may be a semiconductor layer, such as a polysilicon layer. The tunnel insulator 43c is a SiO₂ film, for example. The channel semiconductor layer 43d is a polysilicon layer, for example. The core insulator 43e is a SiO₂ film, for example.

The channel semiconductor layer 43d in each columnar portion 43 is electrically connected to the interconnect 25b (i.e., the bit line) via the plugs 24d and 24c illustrated in FIG. 1, and is also electrically connected to the interconnect 25c (i.e., the source line). Meanwhile, each electrode layer 41 is electrically connected to the interconnect 25b other than bit lines via the plugs 24d and 24c provided below a step region (see FIG. 1) of the memory cell array 22.

The memory cell array 32 includes a plurality of electrode layers 51, a plurality of insulators 52, and a plurality of columnar portions 53 as illustrated in FIG. 2B. FIG. 2B illustrates an example of one of the plurality of columnar portions 53.

The foregoing plurality of electrode layers 51 and the foregoing plurality of insulators 52 are alternately stacked along the Z-direction. Each electrode layer 51 includes a W layer, for example, and functions as a word line or a selection line. Each insulator 52 is a SiO₂ film, for example.

Each columnar portion 53 includes a block insulator 53a, a charge storage layer 53b, a tunnel insulator 53c, a channel semiconductor layer 53d, and a core insulator 53e that are formed in this order on the side faces of the electrode layers 51 and the insulators 52. The block insulator 53a is a SiO₂ film, for example. The charge storage layer 53b is an insulator, such as a SiN film, for example. The charge storage layer 53b may be a semiconductor layer, such as a polysilicon layer. The tunnel insulator 53c is a SiO₂ film, for example. The channel semiconductor layer 53d is a polysilicon layer, for example. The core insulator 53e is a SiO₂ film, for example.

The channel semiconductor layer 53d in each columnar portion 53 is electrically connected to the interconnect 35a (i.e., the bit line) via the plugs 34c and 34b illustrated in FIG. 1, and is also electrically connected to the interconnect 35b (i.e., the source line). Meanwhile, each electrode layer 51 is electrically connected to the interconnect 35a other than bit lines via the plugs 34c and 34b provided below a step region (see FIG. 1) of the memory cell array 32.

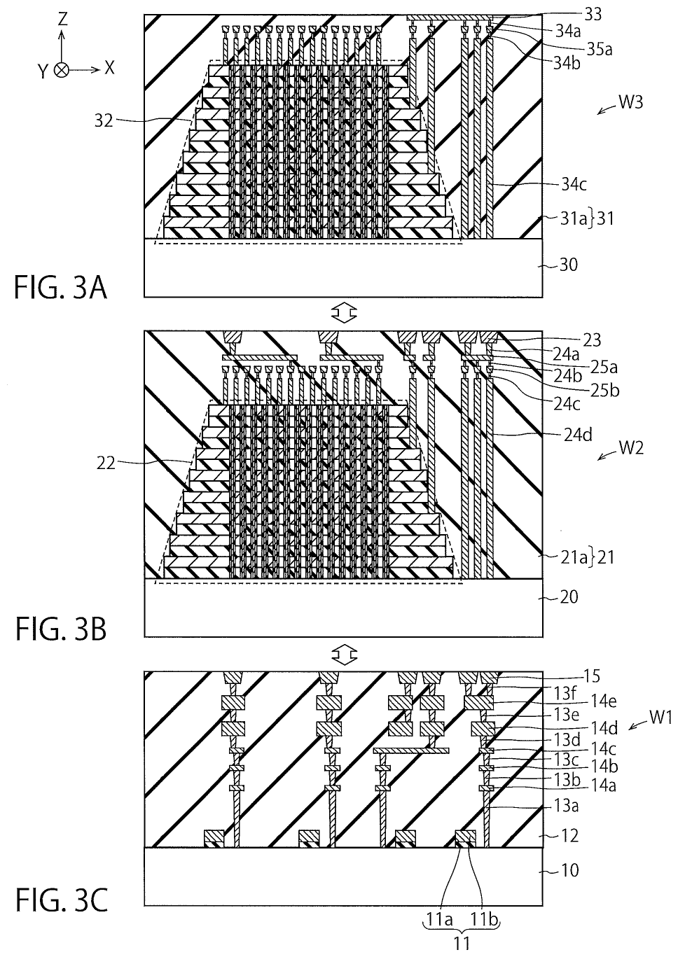

FIGS. 3 to 7 are cross-sectional views illustrating a method of manufacturing the semiconductor device of the first embodiment.

FIG. 3 illustrates a circuit wafer W1 including a plurality of circuit chips 1, an array wafer W2 including a plurality of array chips 2, and an array wafer W3 including a plurality of array chips 3. The circuit wafer W1 is also called a CMOS wafer, and the array wafers W2 and W3 are also called memory wafers.

The orientations of the array wafers W2 and W3 illustrated in FIG. 3 are opposite to those of the array chips 2 and 3 illustrated in FIG. 1. In the present embodiment, a semiconductor device is manufactured by bonding the circuit wafer W1, the array wafer W2, and the array wafer W3 together. FIG. 3 illustrates the array wafers W2 and W3 that are not inverted yet to be bonded together, while FIG. 1 illustrates the array chips 2 and 3 that have been inverted to be bonded together, and then actually bonded together and diced.

In FIG. 3, the array wafer W2 includes a substrate 20 provided below the inter layer dielectric 21, and the array wafer W3 includes a substrate 30 provided below the inter layer dielectric 31. The substrates 20 and 30 are semiconductor substrates, such as Si substrates, for example. Any two of the substrates 10, 20, and 30 are examples of first and second substrates.

The semiconductor device of the present embodiment is manufactured as follows, for example.

First, the transistors 11, the inter layer dielectric 12, the plugs 13a to 13f, the interconnects 14a to 14e, and the metal pads 15 are formed on the substrate 10 of the circuit wafer W1 (FIG. 3). Further, an insulator 21a, the memory cell array 22, the metal pads 23, the via plugs 24a to 24d, and the interconnects 25a to 25b are formed on the substrate 20 of the array wafer W2 (FIG. 3). Furthermore, an insulator 31a, the memory cell array 32, the metal pads 33, the via plugs 34a to 34c, and the interconnects 35a are formed on the substrate 30 of the array wafer W3 (FIG. 3). The insulator 21a is part of the inter layer dielectric 21, and the insulator 31a is part of the inter layer dielectric 31. Regarding the steps illustrated in FIG. 3, the step related to the circuit wafer W1, the step related to the array wafer W2, and the step related to the array wafer W3 may be performed in any order.

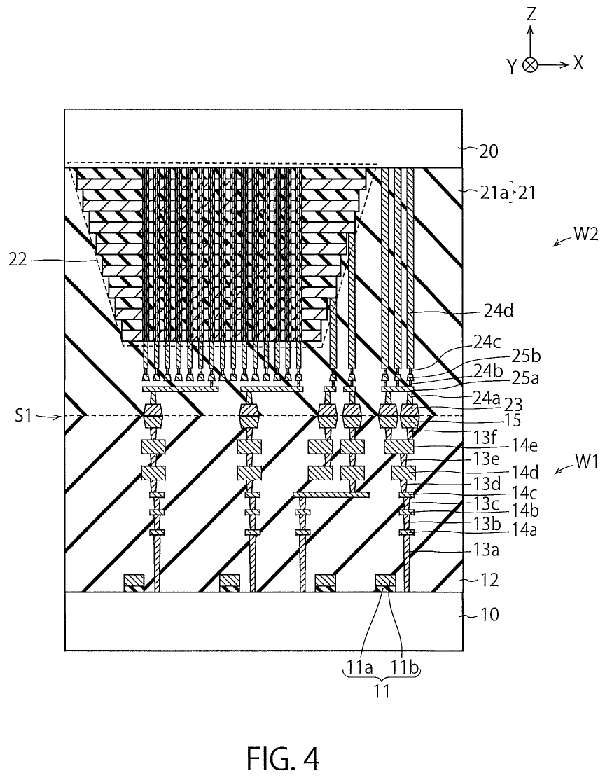

Next, as illustrated in FIG. 4, the circuit wafer W1 and the array wafer W2 are bonded together with mechanical pressure. Accordingly, the inter layer dielectric 12 and the insulator 21a (or the inter layer dielectric 21) are bonded together. Next, the circuit wafer W1 and the array wafer W2 are annealed at 400° C. (FIG. 4). Accordingly, the metal pads 15 and 23 are heated so that the metal pads 15 and 23 are bonded together. In this manner, the substrate 10 and the substrate 20 are bonded together via the inter layer dielectric 12 and the insulator 21a. The lower face of the insulator 21a is bonded to the upper face of the inter layer dielectric 12.

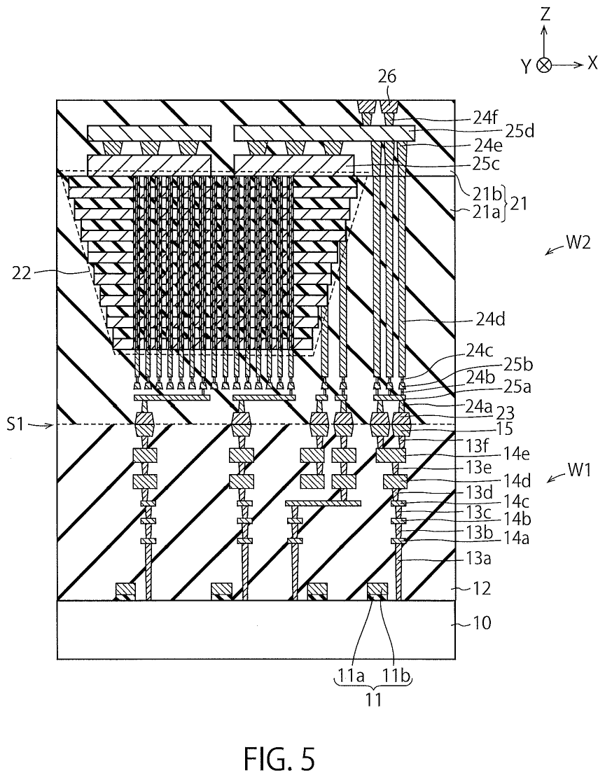

Next, the substrate 20 is removed, and an insulator 21b, the plugs 24e to 24f, the interconnects 25c to 25d, and the metal pads 26 are formed on the insulator 21a and the memory cell array 22 (FIG. 5). The insulator 21b is part of the inter layer dielectric 21. The substrate 20 is removed through CMP (Chemical Mechanical Polishing), for example.

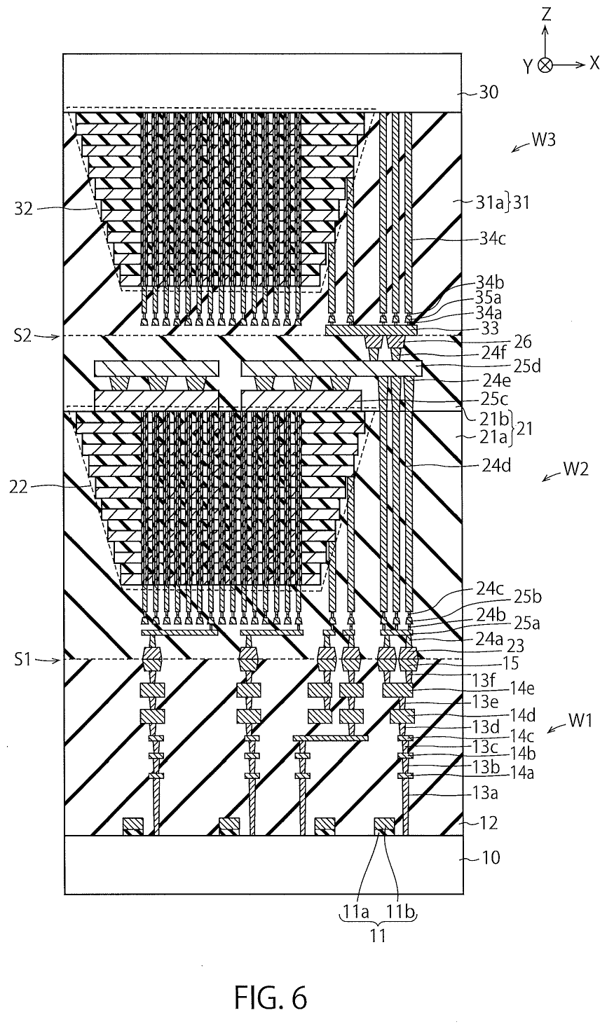

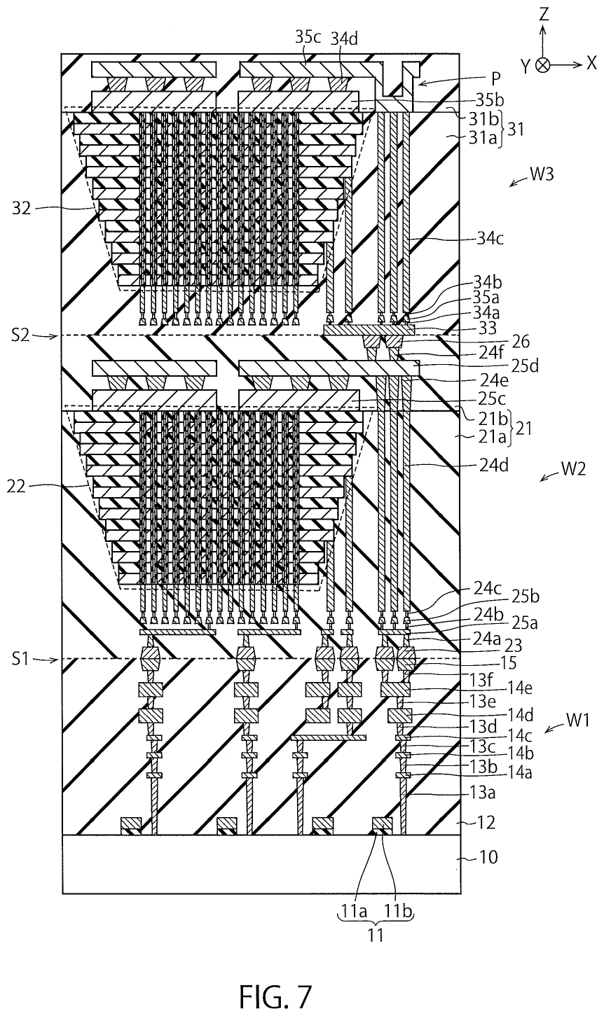

Next, as illustrated in FIG. 6, the array wafer W2 and the array wafer W3 are bonded together with mechanical pressure. Accordingly, the insulator 21b (or the inter layer dielectric 21) and the insulator 31a (or the inter layer dielectric 31) are bonded together. Next, the circuit wafer W1, the array wafer W2, and the array wafer W3 are annealed at 400° C. (FIG. 6). Accordingly, the metal pads 15, 23, 26, and 33 are heated so that the metal pads 26 and 33 are bonded together. Such annealing may be performed so that the metal pads 26 and 33 are heated but the metal pads 15 and 23 are not heated. In this manner, the substrate 10 and the substrate 30 are bonded together via the inter layer dielectric 12, the inter layer dielectric 21, and the insulator 31a. The lower face of the insulator 31a is bonded to the upper face of the insulator 21b. Next, the substrate 30 is removed, and an insulator 31b, the plugs 34d, and the interconnects 35b to 35c are formed on the insulator 31a and the memory cell array 32 (FIG. 7). The insulator 31b is part of the inter layer dielectric 31. The substrate 30 is removed through CMP, for example.

Then, the circuit wafer W1, the array wafer W2, and the array wafer W3 are diced into a plurality of semiconductor chips. In this manner, the semiconductor device illustrated in FIG. 1 is manufactured. The thickness of the substrate 10 may be reduced through CMP before dicing.

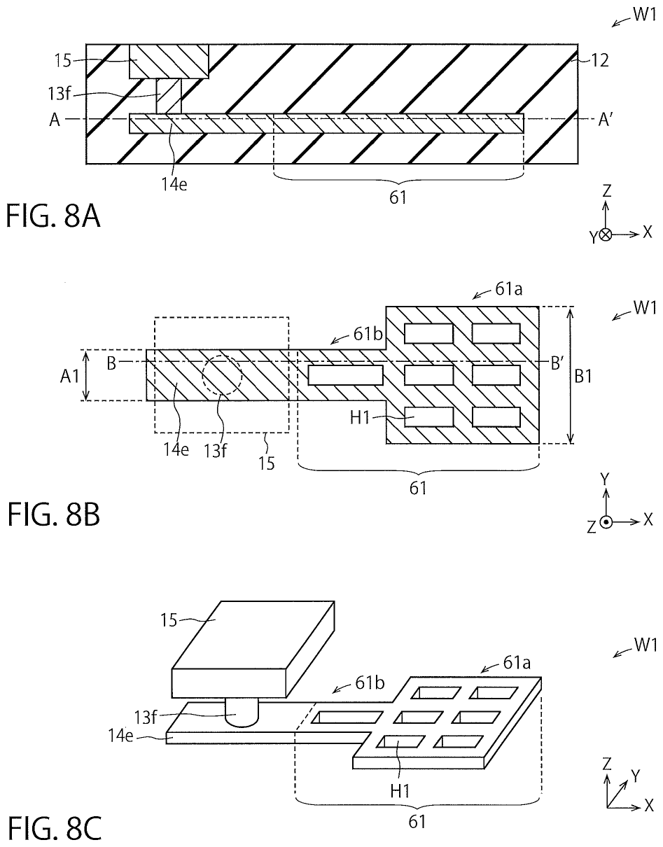

Although the semiconductor device of the present embodiment is manufactured by bonding the circuit wafer W1 and the array wafer W2 together and then bonding the array wafer W2 and the array wafer W3 together, the semiconductor device may be manufactured by bonding the array wafer W2 and the array wafer W3 together and then bonding the circuit wafer W1 and the array wafer W2 together. Alternatively, the semiconductor device of the present embodiment may be manufactured by bonding three or more array wafers together. The foregoing description made with reference to FIGS. 1 to 7 and the following description to be made with reference to FIGS. 8A to 20B are also applicable to be bonding described in the present paragraph.

Although FIG. 1 illustrates the interface between the inter layer dielectrics 12 and 21 and the interface between the metal pads 15 and 23, such interfaces are typically not observable after annealing in FIG. 4 is performed. However, the positions of such interfaces can be estimated by detecting the tilts of the side faces of the metal pads 15 and the side faces of the metal pads 23, or positional deviations between the side faces of the metal pads 15 and the side faces of the metal pads 23, for example. This is also true of the interface between the inter layer dielectrics 21 and 31, the interface between the metal pads 26 and 33, and annealing in FIG. 6.

Next, the further details of the circuit wafer W1, the array wafer W2, and the array wafer W3 of the present embodiment will be described with reference to FIG. 8A to FIG. 10C. Specifically, the structures of the circuit wafer W1, the array wafer W2, and the array wafer W3 before being bonded together will be described.

FIGS. 8A to 8C are views illustrating a structure of the circuit wafer W1 of the first embodiment. FIGS. 8A, 8B, and 8C are respectively a longitudinal cross-sectional view, a transverse cross-sectional view, and a perspective view illustrating the circuit wafer W1. FIG. 8A illustrates a longitudinal cross-section along line B-B′ illustrated in FIG. 8B, and FIG. 8B illustrates a transverse cross-section along line A-A′ illustrated in FIG. 8A.

As illustrated in FIG. 8A, the circuit wafer W1 includes the interconnect 14e including a test pad 61. The test pad 61 is a metal pad used to test the operation of the circuit wafer W1. For example, the test pad 61 is used to test the operation of the foregoing CMOS circuit electrically connected to the test pad 61. During the test, a needle electrically connected to a tester is put on the test pad 61. In FIG. 8A, the circuit wafer W1 includes the plug 13f on a portion of the interconnect 14e other than the test pad 61, and also includes the metal pad 15 on the plug 13f. In the present embodiment, the metal pad 15 is in contact with the plug 13f, while the test pad 61 is not in contact with any plug. Since the test pad 61 of the present embodiment is part of the interconnect 14e, the test pad 61 is provided at a level lower than the metal pad 15. In FIG. 8A, the interconnect 14e, the test pad 61, and the metal pad 15 are respectively examples of the first interconnect, the first pad, and the second pad, and are also examples of a second interconnect, a third pad, and a fourth pad.

In FIG. 8A, the interconnect 14e, the plug 13f, the metal pad 15, and the test pad 61 are formed in the inter layer dielectric 12. However, the upper face of the metal pad 15 is exposed from the inter layer dielectric 12, while the upper face of the test pad 61 is covered with the inter layer dielectric 12. Accordingly, when the circuit wafer W1 and the array wafer W2 are bonded together, the metal pad 15 is in contact with the corresponding metal pad 23, while the test pad 61 is not in contact with any of the metal pads 23. In this manner, the test pad 61 of the present embodiment is not bonded to another metal pad.

As illustrated in FIG. 8B, the test pad 61 of the present embodiment includes a planar portion 61a that is planar in shape as seen in plan view, and a linear portion 61b that is linear in shape as seen in plan view. The test pad 61 of the present embodiment includes a plurality of openings H1 in the planar portion 61a and the linear portion 61b. Consequently, the test pad 61 has a mesh shape as seen in plan view. Such openings H1 penetrate the test pad 61, and are filled with the inter layer dielectric 12. The shape of each opening H1 is rectangular herein, but may also be other shapes. The width in the X-direction and the width in the Y-direction of each opening H1 are set to values in the range of 20 to 60 μm, for example. According to the present embodiment, processing the test pad 61 into a mesh shape makes it possible to suppress the generation of dishing on the upper face of the test pad 61, for example.

In FIG. 8B, the interconnect 14e extends in the X-direction. FIG. 8B illustrates the widths A1 and B1 in the Y-direction of the interconnect 14e. The width A1 indicates the width of a portion of the interconnect 14e other than the test pad 61, and the width of the linear portion 61b. The width B1 indicates the width of the planar portion 61a. In the present embodiment, the width B1 is set greater than the width A1 (B1>A1). The width A1 is an example of a first width, and the width B1 is an example of a second width. According to the present embodiment, setting the width B1 greater than the width A1 makes it possible to increase the area of the test pad 61 (or the planar portion 61a) as seen in plan view, and allow the needle to easily touch the test pad 61. In the present embodiment, the area of the planar portion 61a (including the openings H1) as seen in plan view is larger than the area of the metal pad 15 as seen in plan view.

The interconnect 14e illustrated in FIG. 8B terminates at the test pad 61. That is, the test pad 61 illustrated in FIG. 8B is connected to a portion of the interconnect 14e other than the test pad 61 only at a single point. Specifically, the test pad 61 is connected to a portion of the interconnect 14e other than the test pad 61 only at the left end of the test pad 61 (i.e., the left end of the linear portion 61b).

In FIG. 8B, the positions of the plug 13f and the metal pad 15 are indicated by dashed lines. The positional relationship among the interconnect 14e, the plug 13f, the metal pad 15, and the test pad 61 is also illustrated in FIG. 8C. As illustrated in FIGS. 8B and 8C, the circuit wafer W1 includes the plug 13f on a portion of the interconnect 14e other than the test pad 61, and also includes the metal pad 15 on the plug 13f. Although the test pad 61 in the present embodiment includes the planar portion 61a and the linear portion 61b, the test pad 61 may include only the planar portion 61a instead.

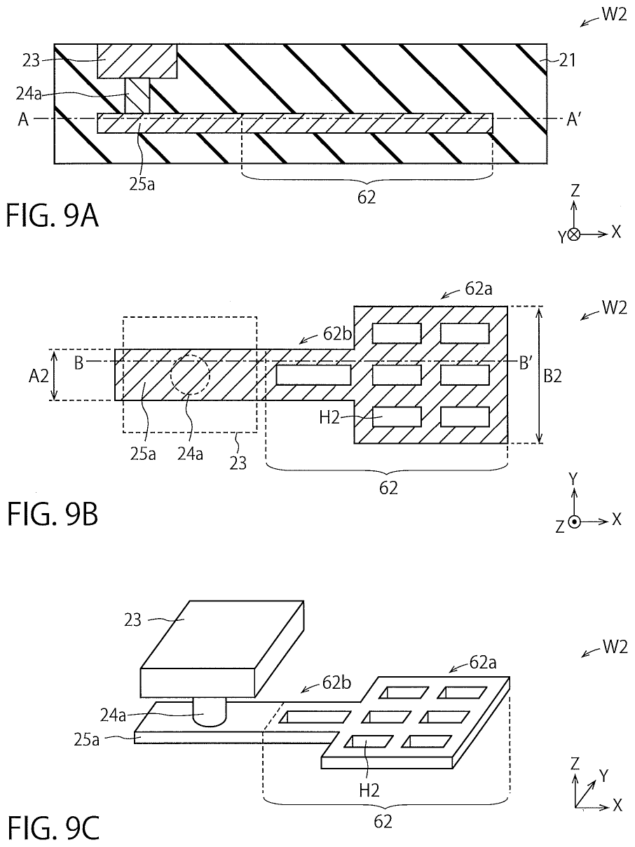

FIGS. 9A to 9C are views illustrating a structure of the array wafer W2 of the first embodiment. FIGS. 9A, 9B, and 9C are respectively a longitudinal cross-sectional view, a transverse cross-sectional view, and a perspective view illustrating the array wafer W2. FIG. 9A illustrates a longitudinal cross-section along line B-B′ illustrated in FIG. 9B, and FIG. 9B illustrates a transverse cross-section along line A-A′ illustrated in FIG. 9A.

As illustrated in FIG. 9A, the array wafer W2 includes the interconnect 25a including a test pad 62. The test pad 62 is a metal pad used to test the operation of the array wafer W2. For example, the test pad 62 is used to test the operation of the memory cell array 22 electrically connected to the test pad 62. During the test, a needle electrically connected to a tester is put on the test pad 62. In FIG. 9A, the array wafer W2 includes the plug 24a on a portion of the interconnect 25a other than the test pad 62, and also includes the metal pad 23 on the plug 24a. The structures of the interconnect 25a, the plug 24a, the metal pad 23, the inter layer dielectric 21, and the test pad 62 illustrated in FIG. 9A are similar to those of the interconnect 14e, the plug 13f, the metal pad 15, the inter layer dielectric 12, and the test pad 61 illustrated in FIG. 8A. In FIG. 9A, the interconnect 25a, the test pad 62, and the metal pad 23 are respectively examples of the first interconnect, the first pad, and the second pad, and are also examples of the second interconnect, the third pad, and the fourth pad.

As illustrated in FIGS. 9B and 9C, the test pad 62 of the present embodiment includes a planar portion 62a and a linear portion 62b, and includes a plurality of openings H2 in the planar portion 62a and the linear portion 62b. FIG. 9B further illustrates the widths A2 and B2 in the Y-direction of the interconnect 25a. The structures of the planar portion 62a and the linear portion 62b illustrated in FIGS. 9B and 9C are similar to the structures of the planar portion 61a and the linear portion 61b illustrated in FIGS. 8B and 8C.

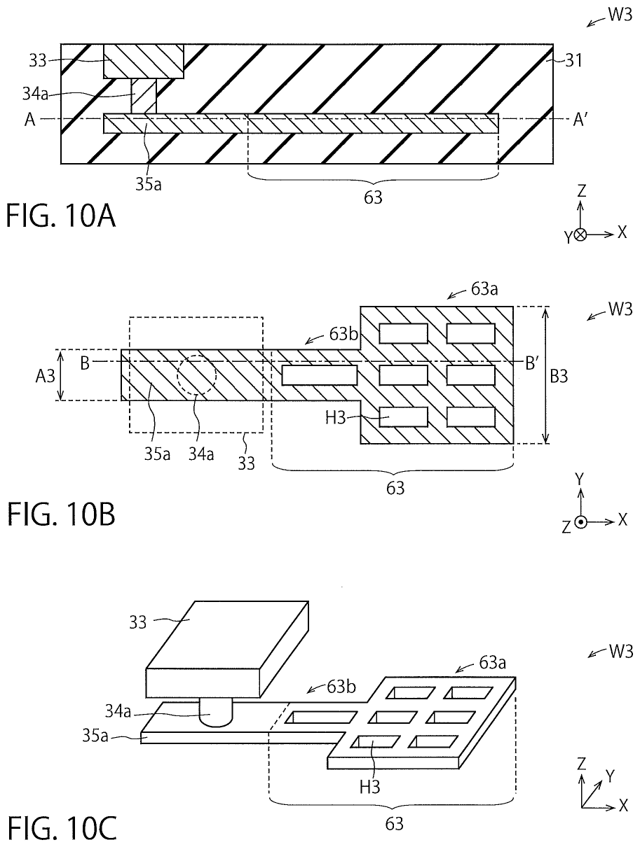

FIGS. 10A to 10C are views illustrating a structure of the array wafer W3 of the first embodiment. FIGS. 10A, 1013, and 10C are respectively a longitudinal cross-sectional view, a transverse cross-sectional view, and a perspective view illustrating the array wafer W3. FIG. 10A illustrates a longitudinal cross-section along line B-B′ illustrated in FIG. 1013, and FIG. 10B illustrates a transverse cross-section along line A-A′ illustrated in FIG. 10A.

As illustrated in FIG. 10A, the array wafer W3 includes the interconnect 35a including a test pad 63. The test pad 63 is a metal pad used to test the operation of the array wafer W3. For example, the test pad 63 is used to test the operation of the memory cell array 32 electrically connected to the test pad 63. During the test, a needle electrically connected to a tester is put on the test pad 63. In FIG. 10A, the array wafer W3 includes the plug 34a on a portion of the interconnect 35a other than the test pad 63, and also includes the metal pad 33 on the plug 34a. The structures of the interconnect 35a, the plug 34a, the metal pad 33, the inter layer dielectric 31, and the test pad 63 illustrated in FIG. 10A are similar to the structures of the interconnect 14e, the plug 13f, the metal pad 15, the inter layer dielectric 12, and the test pad 61 illustrated in FIG. 8A. In FIG. 10A, the interconnect 35a, the test pad 63, and the metal pad 33 are respectively examples of the first interconnect, the first pad, and the second pad, and are also examples of the second interconnect, the third pad, and the fourth pad.

As illustrated in FIGS. 10B and 10C, the test pad 63 of the present embodiment includes a planar portion 63a and a linear portion 63b, and includes a plurality of openings H3 in the planar portion 63a and the linear portion 63b. FIG. 10B further illustrates the widths A3 and B3 in the Y-direction of the interconnect 35a. The structures of the planar portion 63a and the linear portion 63b illustrated in FIGS. 10B and 10C are similar to the structures of the planar portion 61a and the linear portion 61b illustrated in FIGS. 8B and 8C.

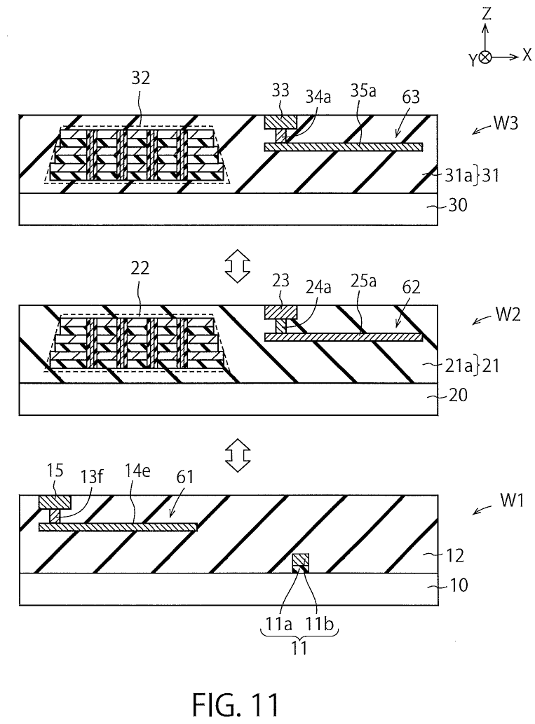

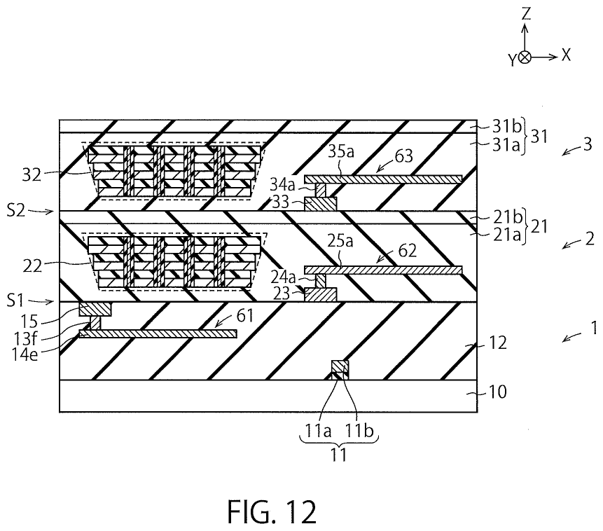

FIGS. 11 and 12 are cross-sectional views illustrating details of the method of manufacturing the semiconductor device of the first embodiment.

FIG. 11 illustrates the circuit wafer W1, the array wafer W2, and the array wafer W3 before being bonded together as in FIG. 3. However, FIG. 11 illustrates only the components related to the test pads 61, 62, and 63, and the illustration of the components not related to the test pads 61, 62, and 63 is omitted. In FIG. 11, the metal pads 15, 23, and 33 are respectively exposed from the inter layer dielectrics 12, 21, and 31, while the test pads 61, 62, and 63 are respectively covered with the inter layer dielectrics 12, 21, and 31.

FIG. 12 illustrates the circuit wafer W1, the array wafer W2, and the array wafer W3 bonded together as in FIG. 7. In FIG. 12, the metal pad 15 is located at the interface (i.e., the bonding face S1) between the inter layer dielectrics 12 and 21, while the test pad 61 is located below the interface and is not in contact with the interface. Similarly, the metal pad 23 is located at the interface (i.e., the bonding face S1) between the inter layer dielectrics 12 and 21, while the test pad 62 is located above the interface and is not in contact with the interface. Similarly, the metal pad 33 is located at the interface (i.e., the bonding face S2) between the inter layer dielectrics 21 and 31, while the test pad 63 is located above the interface and is not in contact with the interface. The metal pads 15, 23, and 33 illustrated in FIG. 12 are respectively joined to the metal pads 23, and 26 (not illustrated).

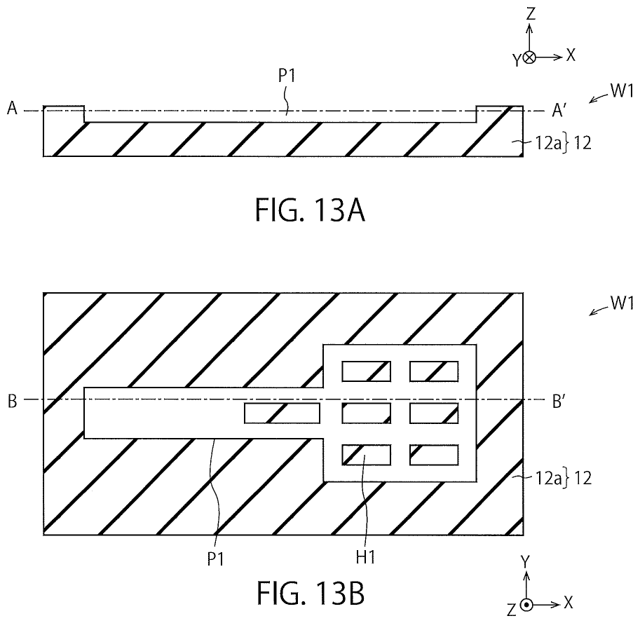

FIGS. 13A to 16B are cross-sectional views illustrating details of the method of manufacturing the semiconductor device of the first embodiment.

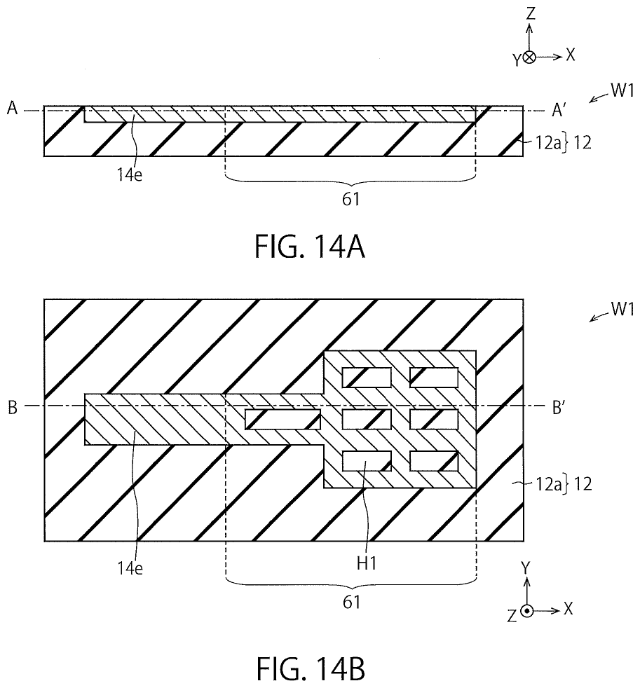

FIG. 13A is a longitudinal cross-sectional view along line B-B′ illustrated in FIG. 13B, and FIG. 13B is a transverse cross-sectional view along line A-A′ illustrated in FIG. 13A. This is also true of FIGS. 14A to 16B. FIGS. 13A to 16B illustrate the steps of forming the test pad 61 and the like of the circuit wafer W1.

First, an insulator 12a, which is part of the inter layer dielectric 12, is formed on the substrate 10 (not illustrated), and then, an interconnect trench P1 is formed in the insulator 12a through RIE (Reactive Ion Etching) (FIGS. 13A and 13B). As described below, the interconnect trench P1 is used to allow the interconnect 14e to be embedded therein. Accordingly, the interconnect trench P1 is formed so as to include “islands of the insulator 12a” to become the openings H1 of the test pad 61 as illustrated in FIG. 13B.

Next, a metal layer for the interconnect 14e is formed on the insulator 12a, and then, a portion of the metal layer outside the interconnect trench P1 is removed through CMP (FIGS. 14A and 14B). Consequently, the interconnect 14e including the test pad 61 is formed in the interconnect trench P1 through single damascene. The interconnect 14e is formed so as to include the openings H1 penetrating the test pad 61. In FIG. 14B, the openings H1 are filled with the insulator 12a. The metal layer for the interconnect 14e may include a Cu (copper) layer, or may include other metal layers (for example, an Al (aluminum) layer or a W (tungsten) layer).

Next, a needle is put on the test pad 61 to test the operation of the circuit wafer W1 (see FIGS. 14A and 14B). For example, the operation of the foregoing CMOS circuit in the circuit wafer W1 can be tested. This test is performed to test the operation of each circuit chip 1 (i.e., each circuit chip area) included in the circuit wafer W1, for example. This makes it possible to determine if each circuit chip 1 in the circuit wafer W1 is defective or non-defective. In such a case, the circuit wafer W1 may include a single test pad 61 in each circuit chip 1. For example, when the circuit wafer W1 includes C circuit chips 1 (where C is an integer of one or more), the circuit wafer W1 may include C test pads 61 for the C circuit chips 1.

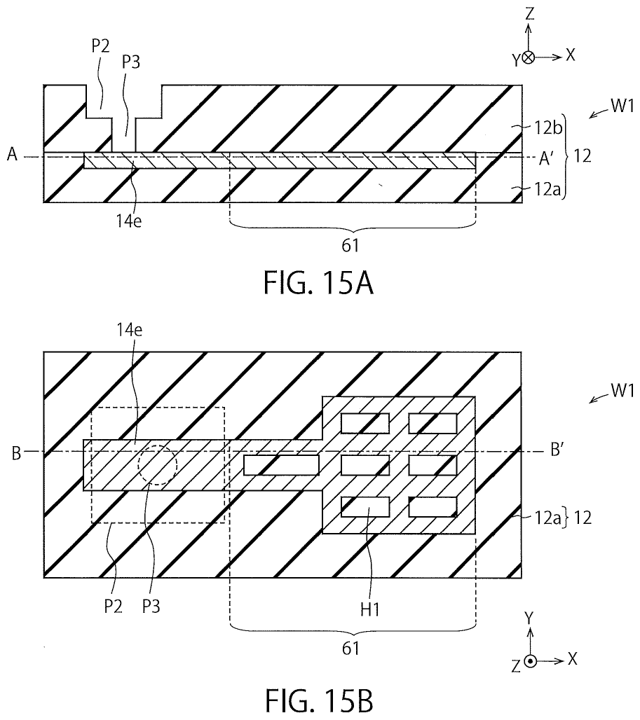

Next, an insulator 12b, which is part of the inter layer dielectric 12, is formed on the insulator 12a and the interconnect 14e, and then, a pad trench P2 and a via hole P3 are formed in the insulator 12b through RIE (FIGS. 15A and 15B). Consequently, a portion of the interconnect 14e other than the test pad 61 is exposed in the via hole P3. The via hole P3 is formed at the bottom portion of the pad trench P2. The test pad 61 is covered with the insulator 12b.

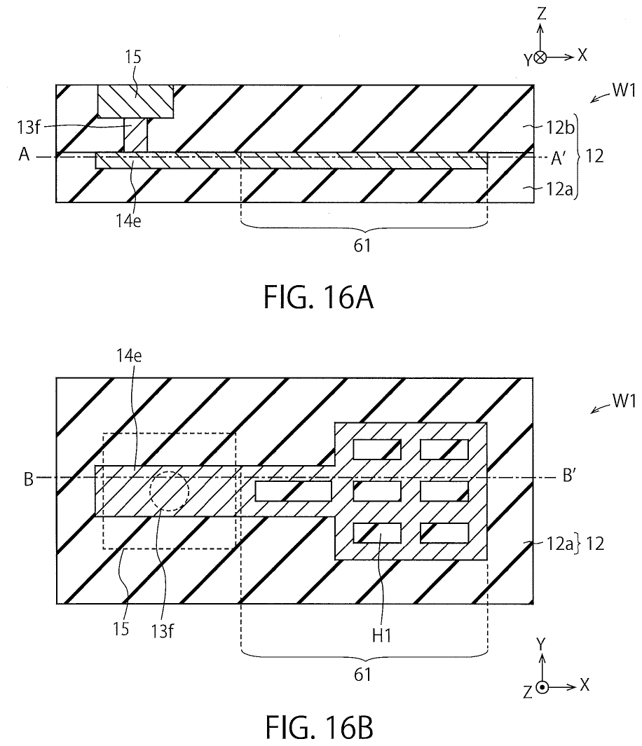

Next, a metal layer for the plug 13f and the metal pad 15 is formed on the insulator 12b, and then, a portion of the metal layer outside the pad trench P2 and the via hole P3 is removed through CMP (FIGS. 16A and 16B). Consequently, the metal pad 15 and the plug 13f are respectively formed in the pad trench P2 and the via hole P3 through dual damascene. The plug 13f is arranged on the interconnect 14e, and the metal pad 15 is formed on the plug 13f. The metal layer for the plug 13f and the metal pad 15 includes a Cu layer, for example.

Then, the circuit wafer W1, the array wafer W2, and the array wafer W3 are bonded together so that the semiconductor device illustrated in FIG. 1 is manufactured.

The test pad 61 of the present embodiment is arranged not in a scribe area but in the circuit chip area (i.e., the circuit chip 1) of the circuit wafer W1. Therefore, the test pad 61 of the present embodiment remains in the circuit chip 1 after dicing.

The test pad 61 of the present embodiment is arranged at a level lower than the metal pad 15, but may be arranged at the same level as the metal pad 15 instead. However, if the test pad 61 is arranged at the same level as the metal pad 15, a scratch formed on the upper face of the test pad 61 by the needle may be exposed at the bonding face S1. Consequently, the scratch may become a cause of the generation of a void in the bonding face S1. Therefore, the test pad 61 is desirably arranged at a level lower than the metal pad 15. However, such a scratch is allowed to disappear if the metal pad 15 and the test pad 61 are formed sufficiently thick, and the upper faces of the metal pad 15 and the test pad 61 are planarized sufficiently through CMP.

The method illustrated in FIGS. 13A to 16B is also applicable to the formation of the test pad 62 of the array wafer W2 and the formation of the test pad 63 of the array wafer W3. In such a case, the tests are performed to test the operation of each array chip 2 (i.e., each array chip area) included in the array wafer W2 and the operation of each array chip 3 (i.e., each array chip area) included in the array wafer W3, for example. This makes it possible to determine if each array chip 2 in the array wafer W2 is defective or not, and also determine if each array chip 3 in the array wafer W3 is defective or not. In such a case, the array wafer W2 may include a single test pad 62 in each array chip 2, and the array wafer W3 may include a single test pad 63 in each array chip 3.

Next, the further details of the tests performed on the circuit wafer W1, the array wafer W2, and the array wafer W3 will be described.

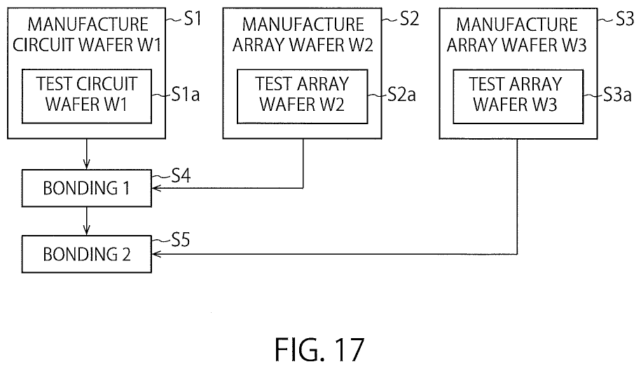

FIG. 17 is a flowchart for illustrating a test method of the first embodiment.

In the present embodiment, steps S1, S2, and S3 of manufacturing the circuit wafer W1, the array wafer W2, and the array wafer W3, respectively, are performed. A test for the circuit wafer W1 is performed as part of step S1 as described with reference to FIGS. 13A to 16B (step S1a). Similarly, a test for the array wafer W2 is performed as part of step S2 (step S2a). Similarly, a test for the array wafer W3 is performed as part of step S3 (step S3a).

After that, the circuit wafer W1 and the array wafer W2 are bonded together (step S4), and then, the array wafer W2 and the array wafer W3 are bonded together (step S5). In this manner, the semiconductor device illustrated in FIG. 1 is manufactured. It is also possible to, after performing step S5, further perform a test for the circuit wafer W1, the array wafer W2, and the array wafer W3 bonded together.

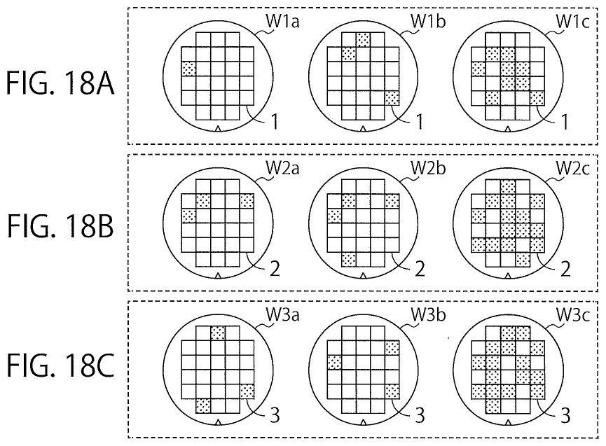

FIGS. 18A to 18C are schematic views for illustrating the test method of the first embodiment.

The semiconductor device of the present embodiment is manufactured by, for example, manufacturing Na circuit wafers W1, Nb array wafers W2, and Nc array wafers W3 (where each of Na, Nb, and Nc is an integer of two or more), and selecting one of the circuit wafers W1, one of the array wafers W2, and one of the array wafers W3, and then bonding the selected circuit wafer W1, array wafer W2, and array wafer W3 together. Such selection is performed based on the results of the tests for the circuit wafers W1, the array wafers W2, and the array wafers W3, for example. Such Na circuit wafers W1, Nb array wafers W2, and Nc array wafers W3 are examples of N first substrates and M second substrates (where each of N and M is an integer of two or more).

FIG. 18A illustrates three circuit wafers W1a to W1c as examples of the Na circuit wafers W1. Each circuit wafer W1 includes a plurality of circuit chips 1 (i.e., circuit chip areas). Similarly, FIGS. 18B and 18C respectively illustrate three array wafers W2a to W2c as examples of the Nb array wafers W2, and three array wafers W3a to W3c as examples of the Nc array wafers W3. Each array wafer W2 includes a plurality of array chips 2 (i.e., array chip areas). Each array wafer W3 includes a plurality of array chips 3 (i.e., array chip areas). Hereinafter, the circuit chip areas of each circuit wafer W1, the array chip areas of each array wafer W2, and the array chip areas of each array wafer W3 shall be respectively expressed as “circuit chip areas 1,” “array chip areas 2,” and “array chip areas 3.” The circuit chip areas 1, the array chip areas 2, and the array chip areas 3 are examples of first and second chip areas.

In FIGS. 18A to 18C, the circuit chip areas 1, the array chip areas 2, and the array chip areas 3 that have been determined to be non-defective in the tests are indicated by white squares (i.e., OK regions), while the circuit chip areas 1, the array chip areas 2, and the array chip areas 3 that have been determined to be defective in the tests are indicated by dot-hatched squares (i.e., NG regions).

For example, a semiconductor chip manufactured from the non-defective circuit chip areas 1, the non-defective array chip areas 2, and the non-defective array chip areas 3 is non-defective. Meanwhile, when at least one of the circuit chip areas 1, the array chip areas 2, and the array chip areas 3 is defective, a semiconductor chip manufactured from such circuit chip areas 1, array chip areas 2, and array chip areas 3 is defective. The foregoing selection is desirably performed so that the proportion of non-defective semiconductor chips becomes high, that is, the yield of the semiconductor chips increases.

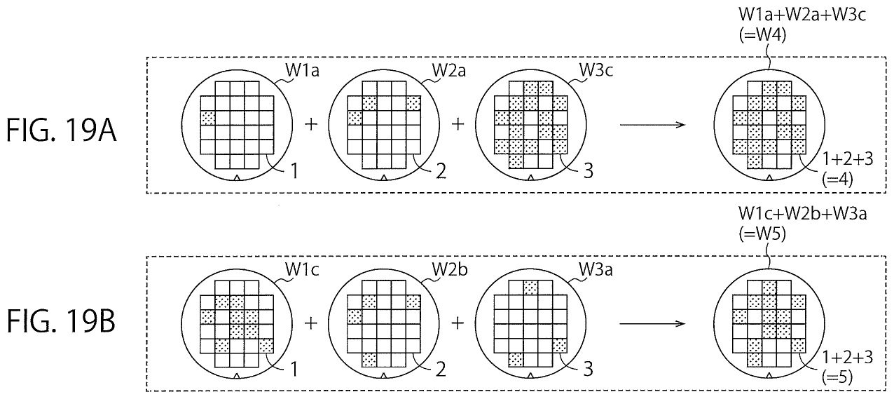

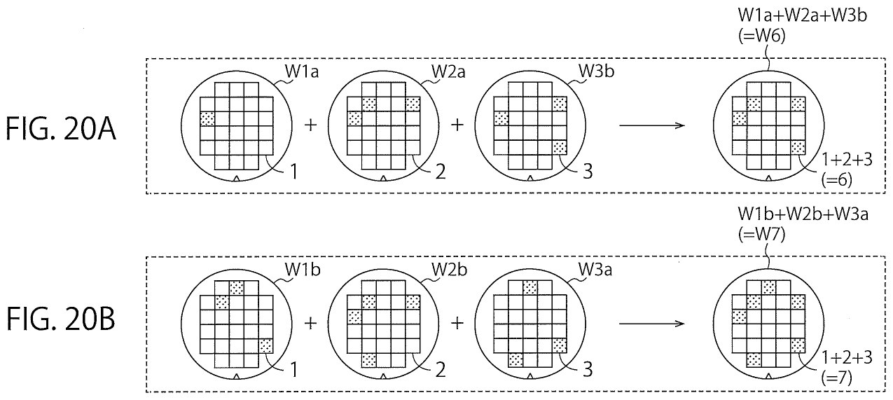

FIG. 18A illustrates the circuit wafers W1a to W1c facing upward. Meanwhile, FIG. 18B illustrates the array wafers W2a to W2c facing downward, and FIG. 18C also illustrates the array wafers W3a to W3c facing downward. That is, FIGS. 18A to 18C illustrate the wafers in a state immediately before they are bonded together. This is also true of FIGS. 19A to 20B described below.

FIGS. 19A and 19B are schematic views for illustrating a test method of a comparative example of the first embodiment.

In FIG. 19A, a semiconductor wafer W4 is manufactured by bonding a circuit wafer W1a, an array wafer W2a, and an array wafer W3c together. The semiconductor wafer W4 includes a plurality of semiconductor chip areas 4 (i.e., semiconductor chips 4). Each semiconductor chip area 4 includes one circuit chip area 1, one array chip area 2, and one array chip area 3.

As described above, the semiconductor chip area 4 including the non-defective circuit chip area 1, the non-defective array chip area 2, and the non-defective array chip area 3 is non-defective. Meanwhile, the semiconductor chip area 4 including the defective circuit chip area 1, the defective array chip area 2, or the defective array chip area 3 is defective. Consequently, the semiconductor wafer W4 in FIG. 19A includes 10 non-defective semiconductor chip areas 4 and 16 defective semiconductor chip areas 4.

In FIG. 19B, a semiconductor wafer W5 is manufactured by bonding a circuit wafer W1c, an array wafer W2b, and an array wafer W3a together. The semiconductor wafer W5 includes a plurality of semiconductor chip areas 5 (i.e., semiconductor chips 5). Each semiconductor chip area 5 includes one circuit chip area 1, one array chip area 2, and one array chip area 3. The semiconductor wafer W5 in FIG. 19B includes 14 non-defective semiconductor chip areas 5 and 12 defective semiconductor chip areas 5.

FIGS. 20A and 20B are schematic views for illustrating the test method of the first embodiment.

In FIG. 20A, a semiconductor wafer W6 is manufactured by bonding a circuit wafer W1a, an array wafer W2a, and an array wafer W3b together. The semiconductor wafer W6 includes a plurality of semiconductor chip areas 6 (i.e., semiconductor chips 6). Each semiconductor chip area 6 includes one circuit chip area 1, one array chip area 2, and one array chip area 3. The semiconductor wafer W6 in FIG. 20A includes 22 non-defective semiconductor chip areas 6 and 4 defective semiconductor chip areas 6.

In FIG. 20B, a semiconductor wafer W7 is manufactured by bonding a circuit wafer W1b, an array wafer W2b, and an array wafer W3a together. The semiconductor wafer W7 includes a plurality of semiconductor chip areas 7 (i.e., semiconductor chips 7). Each semiconductor chip area 7 includes one circuit chip area 1, one array chip area 2, and one array chip area 3. The semiconductor wafer W7 in FIG. 20B includes 20 non-defective semiconductor chip areas 7 and 6 defective semiconductor chip areas 7.

As described above, according to the present embodiment, performing the foregoing selection based on the results of the tests for the circuit wafers W1, the array wafers W2, and the array wafers W3 can increase the yield of semiconductor chips. In FIG. 20A, the circuit wafer W1a, the array wafer W2a, and the array wafer W3b are selected. In FIG. 20B, the circuit wafer W1b, the array wafer W2b, and the array wafer W3a are selected. In the present embodiment, such selection may be manually performed by a human, or automatically performed by a device, such as a computer. In such cases, the foregoing selection may be performed so that the yield of semiconductor chips becomes maximum. At this time, the circuit wafers W1, the array wafers W2, or the array wafers W3 that would increase the number of defective semiconductor chips may be discarded without being used for the manufacture of the semiconductor chips.

As described above, the semiconductor device of the present embodiment includes not only the metal pads 15, 23, 26, and 33 for bonding but also the test pads 61, 62, and 63. Accordingly, the present embodiment makes it possible to increase the yield of semiconductor devices (i.e., semiconductor chips) to be manufactured through bonding.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

1. A semiconductor device comprising:
a first interconnect including a first pad; and
a second pad provided on the first interconnect,
wherein the second pad is in contact with another pad, and the first pad is not in contact with another pad.

2. The device of claim 1, wherein the first pad is a pad for testing a device electrically connected to the first pad.

3. The device of claim 1, wherein
a portion of the first interconnect other than the first pad includes a region with a first width, and
the first pad includes a region with a second width greater than the first width.

4. The device of claim 1, wherein the first pad is connected to a portion of the first interconnect other than the first pad only at a single point.

5. The device of claim 1, wherein the first pad has a mesh shape as seen in plan view.

6. The device of claim 1, further comprising an insulator penetrating the first pad.

7. The device of claim 6, wherein the insulator has a width of 20 to 60 μm as seen in plan view.

8. The device of claim 1, wherein the second pad is provided on a portion of the first interconnect other than the first pad.

9. The device of claim 1, wherein the second pad is provided on the first interconnect via a plug.

10. The device of claim 1, wherein the first pad is not in contact with a plug.

11. The device of claim 1, wherein the first pad is provided at a level lower than the second pad.

12. The device of claim 1, further comprising:
a first insulator;
K second insulators provided on the first insulator, where K is an integer of one or more;
K memory cell arrays respectively provided in the K second insulators; and
a circuit provided in the first insulator and configured to control the K memory cell arrays,
wherein the first interconnect, the first pad and the second pad are provided in the first insulator or in one of the second insulators.

13. The device of claim 12, wherein the second pad is provided at an interface between the first insulator and one of the second insulators, or at an interface between two of the second insulators.

14. The device of claim 12, wherein the first pad is not in contact with the interface.

15. A method of manufacturing a semiconductor device, comprising:
forming a first interconnect including a first pad, on a first substrate;
testing a device electrically connected to the first pad, using the first pad;
forming a second pad on the first interconnect; and
bonding the first substrate and a second substrate after the test performed using the first pad,
wherein the first substrate and the second substrate are bonded such that the second pad is in contact with another pad, and the first pad is not in contact with another pad.

16. The method of claim 15, further comprising:
forming a second interconnect including a third pad, on the second substrate;
testing a device electrically connected to the third pad, using the third pad; and
forming a fourth pad on the second interconnect,
wherein
the first substrate and the second substrate are bonded after the test performed using the first pad and the test performed using the second pad, and
the first substrate and the second substrate are bonded such that the fourth pad is in contact with another pad, and the third pad is not in contact with another pad.

17. The method of claim 16, wherein the first substrate and the second substrate to be bonded are selected from among N first substrates and M second substrates, where N is an integer of two or more, and M is an integer of two or more.

18. The method of claim 17, wherein the first substrate and the second substrate to be bonded are selected from among the N first substrates and the M second substrates, based on a result of the test performed using the first pad, and a result of the test performed using the second pad.

19. The method of claim 18, wherein
the first substrate and the second substrate are bonded after a plurality of first chip areas are formed in the first substrate and a plurality of second chip areas are formed in the second substrate,
the result of the test performed using the first pad includes information related to whether the plurality of first chip areas are defective or not,
the result of the test performed using the second pad includes information related to whether the plurality of second chip areas are defective or not, and
the plurality of first chip areas and the plurality of second chip areas are combined to manufacture a plurality of semiconductor chips.

20. The method of claim 19, wherein the first substrate and the second substrate to be bonded are selected, based on a yield of the plurality of semiconductor chips.
